(19) United States
(12) Patent Application Publication
(10) Pub. No.: US 2014/0173346 A1
(43) Pub. Date: Jun. 19, 2014

(54) VALIDATING OPERATION OF SYSTEM-ON-CHIP CONTROLLER FOR STORAGE DEVICE USING PROGRAMMABLE STATE MACHINE

(71) Applicant: LSI CORPORATION, Milpitas, CA (US)

(72) Inventor: Sachin Shivanand Bastimane, Pune (IN)

(73) Assignee: LSI Corporation, Milpitas, CA (US)

(21) Appl. No.: 13/720,103

(22) Filed: Dec. 19, 2012

(51) Int. Cl. G11C 29/12

(52) U.S. Cl. CPC G11C 29/12
USPC 714/30

(57) ABSTRACT

A system-on-chip includes a storage controller, a read channel integrated circuit, a programmable state machine controller, a switching circuit, a buffer memory, and an interface to access the buffer memory. The switching circuit connects the storage controller or the programmable state machine controller to the read channel integrated circuit. The interface is used to store test control data in the buffer memory. In a given test mode, the switching circuit switchably connects the programmable state machine controller to the read channel integrated circuit. The programmable state machine controller is enabled to access the test control data from the buffer memory, and to process the test control data to generate test signals that are applied to operate the read channel integrated circuit and validate operation of the system-on-chip based on the operation of the read channel integrated circuit.

### FIELD OF THE INVENTION

The field generally relates to techniques for validating operation of system-on-chips for storage devices and, in particular, techniques for utilizing a programmable state machine controller to generate test signals that drive a read channel integrated circuit to validate operation of components of the system-on-chip.

### BACKGROUND

Storage devices such as hard disk drives are used to provide non-volatile data storage in a wide variety of different types of data processing systems. A typical hard disk drive comprises a spindle that holds one or more flat circular storage disks, also referred to as platters. Each storage disk comprises a substrate made from a non-magnetic material, such as aluminum or glass, which is coated with one or more thin layers of magnetic material. In operation, data is read from and written to tracks of the storage disk via a read/write head that is moved precisely across the disk surface by a positioning arm as the disk spins at high speed. Within the storage device, various integrated circuit electronics for controlling the writing and reading of data to and from a storage disk are highly integrated into a single system-on-chip. These integrated circuit electronics include, for example, various micro-controllers such as disk controllers and memory controllers, and other integrated circuits such as read channel integrated circuits, etc., which are configured to operate at ever-increasing speeds for storing and accessing data. To facilitate faster operating speeds, a storage device typically employs a high-speed memory device, such as a double-data rate (DDR) synchronous dynamic random access memory (SDRAM), which serves as a data buffer to maintain consistent data throughput as data passes to and from the storage disks. Since state of the art storage devices implement a relatively large number of complex data processing functions at increasingly higher data rates, it is desirable to implement methods for validating operation of the system-on-chip.

### SUMMARY

In one embodiment of the invention, a system-on-chip for controlling a storage system includes a storage controller, a read channel integrated circuit, a programmable state machine controller, a switching circuit, a buffer memory, and an interface to externally access the buffer memory. The switching circuit operates to switchably connect the storage controller or the programmable state machine controller to the read channel integrated circuit. The buffer memory is connected to the programmable state machine controller. The interface is used to store test control data in the buffer memory. In a test mode to validate operation of the system-on-chip, the switching circuit is controlled to switchably connect the programmable state machine controller to the read channel integrated circuit. In addition, the programmable state machine controller is enabled to access the test control data from the buffer memory, and to process the test control data to generate test signals that are applied to operate the read channel integrated circuit and validate operation of the system-on-chip based on the operation of the read channel integrated circuit.

Other embodiments of the invention will become apparent.

### DESCRIPTION OF THE FIGURES

FIG. 1 shows a perspective view of a disk-based storage device according to an embodiment of the invention.

FIG. 2 shows a plan view of a storage disk in the storage device of FIG. 1.

FIG. 3 schematically illustrates a storage device according to another embodiment of the invention.

FIG. 4 illustrates a system for testing a read channel integrated circuit using a programmable state machine controller according to an embodiment of the invention.

FIG. 5 illustrates a data format for storing test control data in a buffer memory according to an embodiment of the invention.

FIG. 6 is a flow diagram that illustrates a method for using a programmable state machine controller to generate test signals that drive a read channel integrated circuit to validate operation of a system-on-chip, according to an embodiment of the invention.

FIG. 7 illustrates interconnection of the storage device of FIG. 1 with a host processing device in a data processing system.

FIG. 8 shows a virtual storage system incorporating a plurality of disk-based storage devices of the type shown in FIG. 1.

### WRITTEN DESCRIPTION

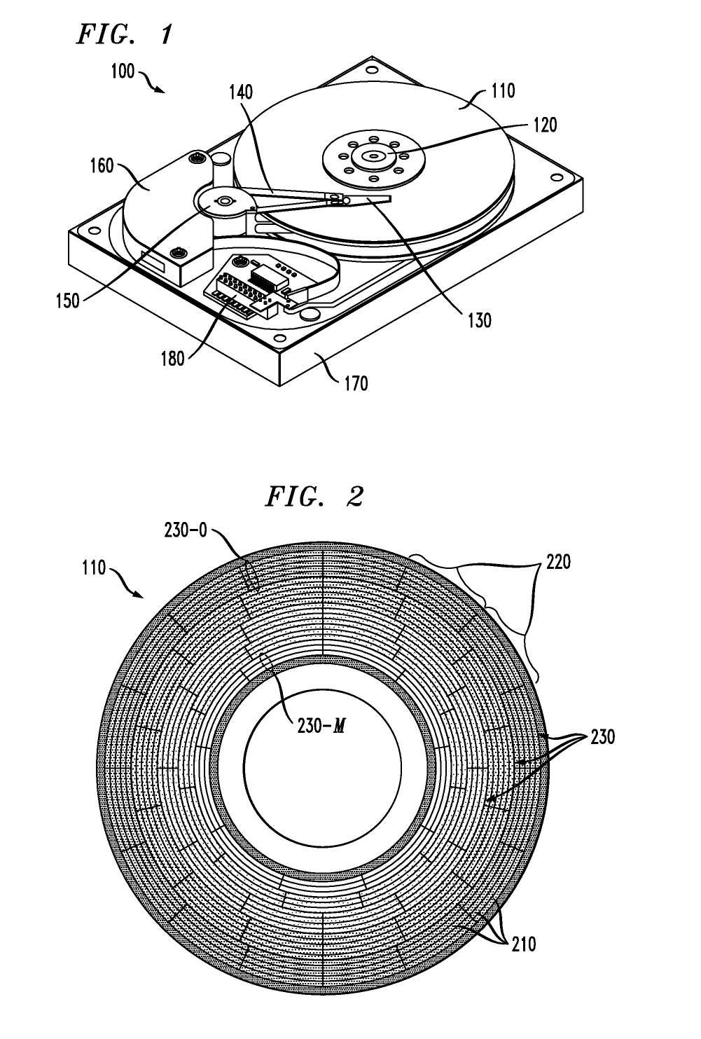

FIG. 1 shows a storage device 100 according to an embodiment of the invention. The storage device 100 comprises a hard disk drive that includes a storage disk 110. The storage disk 110 has a storage surface coated with one or more magnetic materials that are capable of storing data bits in the form of respective groups of media grains oriented in a common magnetization direction (e.g., up or down). The storage disk 110 is connected to a spindle 120. The spindle 120 is driven by a spindle motor (not explicitly shown in FIG. 1) to spin the storage disk 110 at high speed. Data is read from and written to the storage disk 110 via a read/write head 130 that is mounted on a positioning arm 140. An actuator motor 150 (or voice coil motor) is connected to one end of the positioning arm 140 opposite the read/write head 130. The actuator motor 150 comprises a permanent magnet and a moving coil motor, which operate to controllably swing the read/write head 130 into a desired position across the magnetic surface of the storage disk 110 as the storage disk 110 spins by operation of the spindle motor. The storage device 100 further comprises an upper housing 160 which houses driver circuitry and other mechanical and electronic components for controlling the actuator motor 150 and the spindle motor. The upper housing 160 further comprises control circuitry such as preamplifier electronics that are mounted proximate to the pivot location of the actuator motor 150. Thin printed-circuit cables are used to connect the read/write heads 130 to the preamplifier electronics mounted in the housing 160.

The storage device 100 further comprises other control circuitry mounted on or more printed circuit boards that are disposed in a lower housing 170 of the storage device 100. The control circuitry comprises various drive electronics, signal processing electronics, and associated processing and memory circuitry, to control the writing and reading of data to and from the storage disk, as well as additional or alternative elements that are utilized to drive and control the spindle and actuator motors. A connector 180 is used to connect the storage device 100 to a host computer or other related processing device.

FIG. 1 shows an embodiment of the invention with one instance of each of the single storage disk 110, read/write head 130, and positioning arm 140. In an alternate embodiment of the invention, the storage device 100 comprises multiple instances of one or more of these or other drive components. For example, in an alternative embodiment of the invention, the storage device 100 comprises multiple storage disks attached to the same spindle such that each storage disk rotates at the same speed, as well as multiple read/write heads and associated positioning arms coupled to one or more actuators.

A read/write head as that term is broadly used herein may be implemented in the form of a combination of separate read and write heads. More particularly, the term “read/write” as used herein is intended to be construed broadly as read and/or write, such that a read/write head may comprise a read head only, a write head only, a single head used for both reading and writing, or a combination of separate read and write heads. Such heads may comprise, for example, write heads with wrap-around or side-shielded main poles, or any other types of heads suitable for recording and/or reading data on a storage disk.

In addition, the storage device 100 as illustrated in FIG. 1 may include other elements in addition to, or in place of, those specifically shown, including one or more elements of a type commonly found in conventional storage devices. These and other conventional elements, being well understood by those skilled in the art, are not described in detail herein. It should also be understood that the particular arrangement of elements shown in FIG. 1 is presented by way of illustrative example only. Those skilled in the art will recognize that a wide variety of other storage device configurations may be used in implementing embodiments of the invention.

FIG. 2 shows the storage surface of the storage disk 110 in greater detail. As illustrated, the storage surface of storage disk 110 comprises a plurality of concentric tracks 210. Each track is subdivided into a plurality of sectors 220 that are capable of storing a block of data for subsequent retrieval. The tracks located toward the outside edge of the storage disk have a larger circumference when compared to those located toward the center of the storage disk. The tracks are grouped into several annular zones 230, where the tracks within a given one of the zones have the same number of sectors. Those tracks in the outer zones have more sectors than those located in the inner zones. In this example, it is assumed that the storage disk 110 comprises M+1 zones, including an outermost zone 230-0 and an innermost zone 230-M.

The outer zones of the storage disk 110 provide a higher data transfer rate than the inner zones. This is in part due to the fact that the storage disk in the present embodiment, once accelerated to rotate at operational speed, spins at a constant angular or radial speed regardless of the positioning of the read/write head, but the tracks of the inner zones have smaller circumference than those of the outer zones. Thus, when the read/write head 130 is positioned over one of the tracks of an outer zone, it covers a greater linear distance along the disk surface for a given 360° turn of the storage disk than when it is positioned over one of the tracks of an inner zone. Such an arrangement is referred to as having constant angular velocity (CAV), since each 360° turn of the storage disk takes the same amount of time, although it should be understood that CAV operation is not a requirement of embodiments of the invention.

Data bit density is generally constant across the entire storage surface of the storage disk 110, which results in higher data transfer rates at the outer zones. Accordingly, the outermost annular zone 230-0 of the storage disk has a higher average data transfer rate than the innermost annular zone 230-M of the storage disk. The average data transfer rates may differ between the innermost and outermost annular zones in a given embodiment of the invention by more than a factor of two. For example, in one embodiment of the invention, the outermost annular zone may have a data transfer rate of approximately 2.3 Gigabits per second (Gb/s), while the innermost annular zone has a data transfer rate of approximately 1.0 Gb/s. In such an implementation, the hard disk drive may more particularly have a total storage capacity of 500 GB and a spindle speed of 7200 RPM, with the data transfer rates ranging, as noted above, from about 2.3 Gb/s for the outenuost zone to about 1.0 Gb/s for the innermost zone.

The storage disk 110 may be assumed to include a timing pattern formed on its storage surface. Such a timing pattern may comprise one or more sets of servo address marks (SAMs) or other types of servo marks formed in particular sectors in a conventional manner. SAMs may therefore be viewed as an example of what are more specifically referred to herein as servo marks. The particular data transfer rates and other features described above are presented for purposes of illustration only, and should not be construed as limiting in any way. A wide variety of other data transfer rates and storage disk configurations may be used in other embodiments.

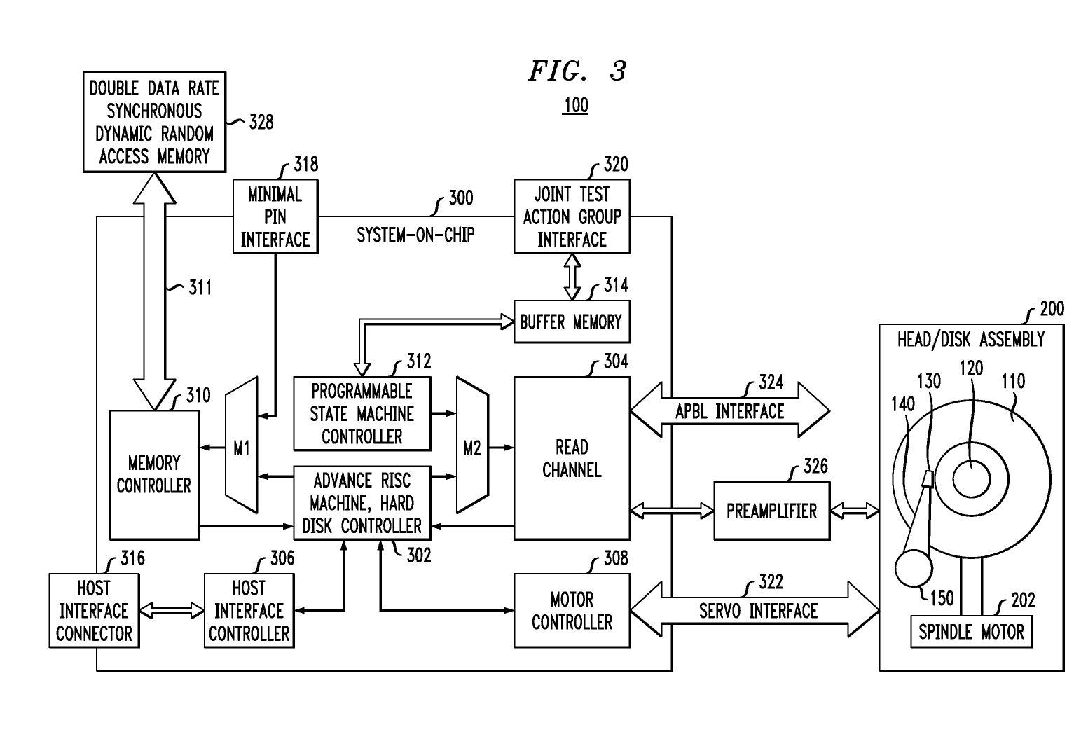

FIG. 3 schematically illustrates a storage device according to another embodiment of the invention. In particular, FIG. 3 illustrates an embodiment of the storage device 100 of FIG. 1 in greater detail. As shown in FIG. 3, the storage device 100 comprises a read/write head and disk assembly 200 and a system-on-chip 300. The read/write head and disk assembly 200 comprises components such as a storage disk 110, spindle 120, read/write head 130, positioning arm 140, actuator motor 150, and a spindle motor 202, as discussed above with reference to the embodiment of FIG. 1. The system-on-chip 300 comprises various integrated circuits such as a hard disk controller 302, a read channel integrated circuit 304, a host interface controller 306, a motor controller 308, a memory controller 310, a programmable state machine controller 312, a buffer memory 314, a first multiplexer M1, and a second multiplexer M2. The system-on-chip 300 further comprises a plurality of interfaces such as a host interface connector 316, a minimal pin interface 310, a Joint Test Action Group (JTAG) interface 320, a servo interface 322, and a bidirectional APBL (Advanced Peripheral Bus-Light) interface 324. The storage device 100 further comprises a preamplifier 326 and an external random access memory 328.

The host interface connector 316 represents a physical connector (e.g., connector 180 as shown in FIG. 1) and associated input/output (I/O) bus wiring that connects the storage device 100 to a host system, device, I/O bus, or other components of a data processing system. The I/O data is moved to and from the storage device 100 through the host interface connector 316 under control of the host interface controller 306. The host interface controller 306 implements communication protocols for communicating with a host system or device and controlling and managing data I/O operations, using one or more known interface standards. For example, in one or more alternative embodiments of the invention, the host interface connector 316 and host interface controller 306 are implemented using one or more of Small Computer interface (SCSI), Serial Attached SCSI (SAS), Serial Advanced Technology Attachment (SATA) and/or Fibre Channel (FC) interface standards, for example.

The hard disk controller 302 controls the overall operations of writing and reading data to and from the storage disk 110. In one embodiment of the invention, the hard disk controller 302 is an ARM (Advanced Reduced instruction set computing Machine). In other embodiments, the hard disk controller 302 may comprise other known architectures suitable for controlling hard disk operations. The read channel integrated circuit 304 encodes and decodes data that is written to and read from the storage disk 110 using the read/write head 130. The preamplifier 326 is connected between the read channel integrated circuit 304 and the read/write head 130. The preamplifier 326 amplifies an analog signal output from the read/write head 130 for input to the read channel integrated circuit 304 and provides a voltage bias for a magnetic sensor of the read/write head 130. The APBL interface 324 is used to access internal registers of the read channel integrated circuit 304.

The motor controller 308 is connected to the head/disk assembly 200 via the servo interface 322. The motor controller 308 sends control signals to the spindle motor 202 and actuator motor 150 through the servo interface 322 during read and write operations to spin the storage disk 110 and move the read/write head 130 into a target position. In particular, for a typical read operation, signals for performing a read operation are received through the host interface connector 316 and sent to the hard disk controller 302 through the host interface controller 306. The hard disk controller 302 processes the read signals for performing the read operation and then sends control signals to the motor controller 308 for controlling the actuator motor 150 and spindle motor 202 for the read operation. Additionally, the hard disk controller 302 sends the processed read signals to the read channel integrated circuit 304, which are then sent to the actuator motor 150 through the preamplifier 326 to perform the read operation. The actuator motor 150 positions the read/write head 130 over a target data track on storage disk 110 in response to control signals received by the motor controller 308 and the read channel integrated circuit 304. The motor controller 308 also generates control signals to drive the spindle motor 202 to spin the storage disk 110 under the direction of the hard disk controller 302. The spindle motor 202 spins the storage disk 110 at a determined spin rate.

When the read/write head 130 is positioned adjacent the target data track, magnetic signals representing data on the storage disk 110 are sensed by read/write head 130 as the storage disk 110 is rotated by the spindle motor 202. The sensed magnetic signals are provided as continuous, minute analog signals representative of the magnetic data on the storage disk 110. The analog signals are transferred from the read/write head 130 to the read channel integrated circuit 304 via the preamplifier 326. The preamplifier 326 amplifies the analog signals accessed from storage disk 110, and the read channel integrated circuit 304 decodes and digitizes the received analog signals to recreate the information originally written to the storage disk 110. The data read from the storage disk 110 is then output to a host system or device through the host interface controller 306 and host interface connector 316 under control of the hard disk controller 302.

A write operation is substantially the opposite of a read operation. For example, in one embodiment, write signals for performing write operations are received through the host interface connector 316, wherein the write signals represent commands to perform a write operation and/or data that is to be written to the storage disk 110. The write signals are sent to the hard disk controller 302 through host interface controller 306. The hard disk controller 302 processes the write signals for performing the write operation and then sends control signals to the motor controller 308 for controlling the actuator motor 150 and spindle motor 202 for the write operation. Additionally, the hard disk controller 302 sends the processed write signals (and formatted data) to the read channel integrated circuit 304, wherein the formatted data to be written is encoded. The write signals (control and data) are then sent to the actuator motor 150 through the preamplifier 326 to perform a write operation by writing data to the storage disk 110 via the read/write head 130.

In the embodiment of FIG. 3, the external random access memory 328 is an external memory relative to the system-on-chip 300 and other components of the storage device 100, but is nonetheless internal to the storage device 100. In one embodiment, the external random access memory 328 is a double data rate synchronous dynamic random access memory, although a wide variety of other types of memory may be used in alternate embodiments. The external random access memory 328 is initialized by the memory controller 310. The memory controller 310 performs signaling control of the external random access memory 328 on behalf of the hard disk controller 302, whereby initialization of the external random access memory 328 is implemented via the programming of configuration registers in the memory controller 310 by the disk controller 302. In operation, the memory controller 310 generates internal clock pulses for synchronizing data write operations and read operations of the external random access memory 328. The internal clock signals and data are transmitted to and from the external random access memory 328 via a data/signal bus 311.

In one embodiment of the invention, the external random access memory 328 serves as a buffer memory for data transfers between a host system/device and the storage device 100. For example, the read and or write signals (as discussed above) that are received by the hard disk controller 302 from the host interface controller 306 can be temporarily stored in the external random access memory 328 before being processed by the hard disk controller 302 and the read channel integrated circuit 304, for example. Moreover, data that is read out from the storage disk 110 may be temporarily stored in the external random access memory 328 before being packaged and output to a host system/device by operation of the hard disk controller 302 and the host interface controller 306. This buffering optimizes the throughput of the storage device 100 by matching disparate processing and data transmission speeds as data passes to and from the storage disk 110.

The first multiplexer M1 is a switching circuit that has inputs connected to the minimal pin interface 318 and the hard disk controller 302, and an output connected to the memory controller 310. The first multiplexer M1 is used during a test mode to switchably connect the minimal pin interface 318 to the memory controller 310 and allow input of external test control signals and initialization parameters to debug initialization issues or otherwise validate operation of the external random access memory 328 using known techniques.

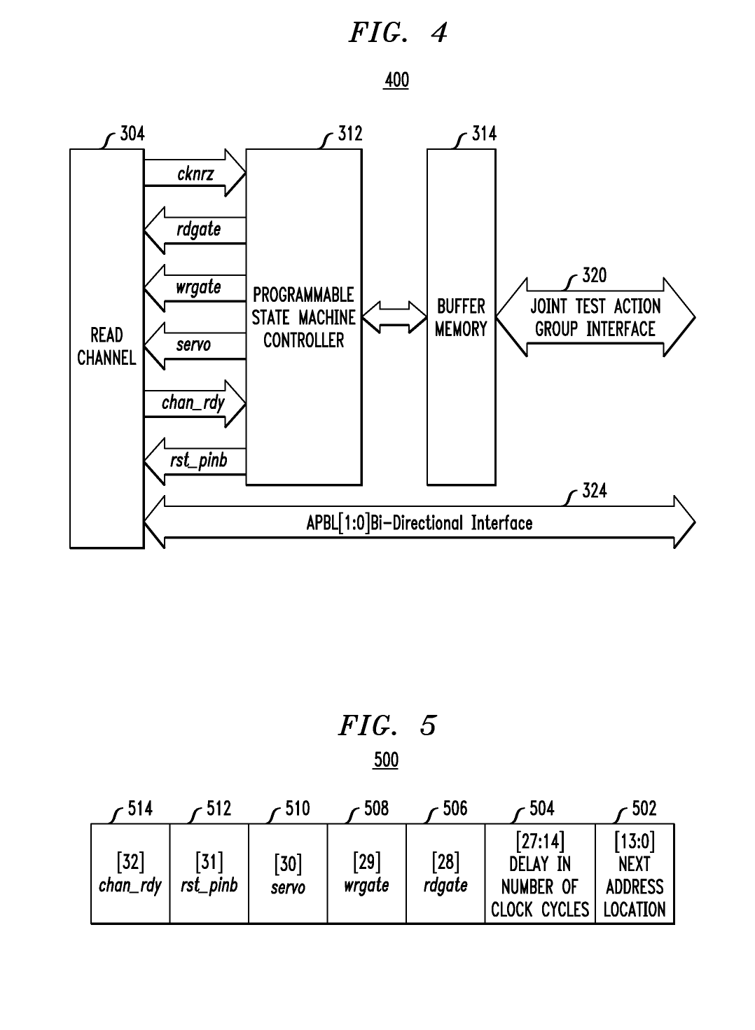

Moreover, the second multiplexer M2 is a switching circuit having inputs connected to the disk controller 302 and the programmable state machine controller 312, and an output connected to the read channel integrated circuit 304. The buffer memory 314 is connected to the programmable state machine controller 312. In one embodiment of the invention, the buffer memory 314 stores test control data that is input to the buffer memory 314 using the JTAG interface 320. The test control data is processed by the programmable state machine controller 312 during a test mode to validate operation of components of the system-on-chip 300. For example, in one embodiment of the invention, the second multiplexer M2 switchably connects the programmable state machine controller 312 to the read channel integrated circuit 304 to execute a test mode of the system-on-chip 300. In one embodiment of the invention, a test mode is performed by enabling the programmable state machine controller 312 to access the test control data from the buffer memory 314 and processes the test control data to generate test control signals that are applied to operate the read channel integrated circuit 304 and validate operation of the system-on-chip 300 based on the operation of the read channel integrated circuit 304. Details regarding test mode procedures that can be implemented using the programmable state machine controller 312 according to alternative embodiments of the invention will be discussed below with reference to FIGS. 4, 5, and 6, for example.

It is to be understood that the external random access memory 328, system-on-chip 300 and preamplifier 326 shown in FIG. 3 collectively represent one embodiment of “control circuitry” as that term is utilized herein. Numerous alternative embodiments of “control circuitry” include a subset of the components 300, 326 and 328 or portions of one or more of these components. For example, the system-on-chip 300 itself may be viewed as an example of “control circuitry” to process data received from and supplied to the read/write head 130 and to control positioning of the read/write head 130 relative to the storage disk 110. Certain operations of the system-on-chip 300 in the storage device 100 of FIG. 3 may be directed by the disk controller 302, which executes code stored in the external random access memory 328 and/or the internal buffer memory 314, for example. Thus, at least a portion of the control functionality of the storage device 100 may be implemented at least in part in the form of software code.

Furthermore, although the embodiment of FIG. 3 illustrates various components of the system-on-chip 300 being implemented on a single integrated circuit chip, the system-on-chip 300 may include other integrated circuits, such as the external random access memory 328 or the preamplifier 326, or portions thereof. Moreover, the disk controller 302, host interface controller 306, motor controller 308, and programmable state machine controller 314, may be implemented using suitable integrated circuit architectures such as microprocessor, digital signal processor (DSP), application-specific integrated circuit (ASIC), or field-programmable gate array (FPGA), or other types of integrated circuit architectures.

FIG. 4 illustrates a system for testing a read channel integrated circuit using a programmable state machine controller according to an embodiment of the invention. More specifically, FIG. 4 illustrates a test system 400 which comprises the read channel integrated circuit 304, programmable state machine controller 312, buffer memory 314, and JTAG interface 320 components of the system-on-chip 300 of FIG. 3, which are used to validate operation of the system-on-chip 300 using one of various test modes. In one embodiment of the invention, a test mode is implemented to verify the effects on the external random access memory 328 due to supply voltage noise that is generated by operation of the read channel 302.

In an embodiment where the external random access memory 328 is implemented as a DDR SDRAM, for example, the higher data rate speeds of the external random access memory 328 can present issues regarding the timing of data transfers. The memory controller 310 in FIG. 3 generates internal clock pulses for synchronizing data write operations and read operations of the external random access memory 328. Data is transferred at both the rising edge and falling edge of the clock pulses. In this regard, the timing requirements of a DDR memory demand a more precise synchronization for both data write and read operations as synchronization problems may result in errors while reading data from and writing data to the external random access memory 328. These clock and/or control signals may become desynchronized due to physical characteristics of the integrated circuit components that are part of the system-on-chip 300 or mounted on a same printed circuit board as the system-on-chip 300, as well as changes in the environment in which the external memory 328 is operating. For example voltage and temperature changes can cause drift from an optimal operating point of the external random access memory 328. Moreover, voltage and temperature changes can cause jitter and skew of the data and timing control signals that are output from the memory controller 310 to the external random access memory 328.

In the embodiment shown in FIG. 3, the read channel integrated circuit 304 uses a significant amount of power when it is active, which can result in substantial voltage transients, e.g., voltage fluctuation and jitter, during a functional mode of operation of the read channel integrated circuit 304. These voltage transients can adversely affect the read and write operations of the external random access memory 328 due to, e.g., undesired skew of data and control signals that are generated and output from the memory controller 310 and transmitted to the external memory 328 via the bus 311. In this regard, in one embodiment of the invention, a test mode is implemented for validating operation of the system-on-chip 300 with respect to the functionality of the memory controller 310 and the external random access memory 328 under test mode conditions in which the read channel integrated circuit 304 is active and operating in a functional mode.

For example, in one embodiment of the invention, a test mode is implemented in which test signals for driving the read channel integrated circuit 304 are generated by the programmable state machine controller 312 based on test control data and commands that are stored in the internal buffer memory 314. The programmable state machine controller 312 processes the test control data and commands stored in the internal buffer memory 314 to generate test signals (I/O signals) that drive the read channel integrated circuit 304 to emulate write and read cycles similar to those generated during a functional mode of operation of the read channel integrated circuit 304. In this test mode, the programmable state machine controller 312 drives the read channel integrated circuit 304 with test signal waveforms to generate voltage transients or supply noise, which are similar to voltage transients and noise that would be generated during a functional mode of operation of the read channel integrated circuit 304. The voltage transients and/or supply noise generated in this manner are used to determine the effects of functional mode operation of the read channel integrated circuit 304 on the memory controller 310 and/or the external random access memory 328 when reading/writing data to the storage disk 110 by the system-on-chip 300.

In one embodiment of the invention, the internal buffer memory 314 is used by the system-on-chip 300 as a buffer memory for normal functional mode operations. In one embodiment of the invention, the internal memory buffer 314 is used as a LLI (Long Latency Interface) buffer memory for normal functional mode operations of the system-on-chip 300. The internal buffer memory 314 is reused for test modes to store control signals and commands that are used by programmable state machine controller 312 for driving the read channel integrated circuit 304. The programmable state machine controller 312 is programmed through the JTAG interface 320 to generate different test signal waveforms to emulate different operating behaviors of the read channel integrated circuit 304.

FIG. 4 shows test signals and clock signals that are transmitted between the programmable state machine controller 312 and the read channel integrated circuit 304. A clock signal, cknrz, is a non-return-to-zero (NRZ) symbol-rate read data clock that is generated by the read channel integrated circuit 304. The LLI protocol uses a source-synchronous architecture for its outputs, and all synchronous LLI outputs of the read channel integrated circuit 304 are synchronous to the cknrz clock. In one embodiment of the invention shown in FIG. 4, the programmable state machine controller 312 is synchronized to the cknrz clock output from the read channel integrated circuit 304. In this manner, the test signals that are input to the read channel integrated circuit 304 from the programmable state machine controller 312 are synchronized to the actual functional frequency of the read channel integrated circuit 304 so that the testing and validation operations can be close to or at real-time functional mode simulation.

As further shown in FIG. 4, a rdgate signal is a read gate signal that is asserted at a rdgate input port of the read channel integrated circuit 304 to initiate a read operation. A wrgate signal is a write gate signal that is asserted at an input port of the read channel integrated circuit 304 to initiate a write operation. A servo signal is a control signal that is input to a servo gate input of the read channel integrated circuit 304 to initiate a servo operation. A chan_rdy signal is sent from the read channel integrated circuit 304 to as a channel ready indicator signal. The assertion of the chan_rdy output port indicates that the read channel integrated circuit 304 is prepared to initiate a sector read or write. In write mode, assertion of chan_rdy indicates that the read channel integrated circuit 304 has sufficient data to begin a sector write without risk of underflow. A rst_pinb is a reset signal which, in one embodiment, is an active low reset signal. Furthermore, as noted above, the APBL interface 324 is a register interface that is used to access internal registers of the read channel integrated circuit 304. The APBL interface 324 includes a ck_apbl clock input signal, as well as a bidirectional apbl[1:0] I/O signal. The direction of the I/O is controlled through a read channel APBL control signal.

FIG. 5 illustrates a data format for storing test control data in a buffer memory according to an embodiment of the invention. FIG. 5 illustrates a format of a single data block 500 for storing test control data in the buffer memory 314. The test control data comprises a linked sequence of multiple data blocks which are sequentially accessed and processed by the programmable state machine controller 312 to generate the test controls signals that are applied to the read channel integrated circuit 304 for a given test mode. In one embodiment of the invention as shown in FIG. 5, each data block 500 comprises a plurality of data block portions 502, 504, 506, 508, 510, 512 and 514.

The data block portion 502 specifies an address location of a next data block in the linked sequence of data blocks. In one embodiment of the invention, the data block portion 502 is a 14-bit [13:0] data block that specifies a next address location in the buffer memory 314 at which the programmable state machine controller 312 will access a next data next block 500 in the linked sequence of data blocks when executing a test mode of operation. The data block portion 504 is a 14-bit data block [27:14] that specifies a delay in number of cknrz clock cycles to wait after applying test signals for the given data block to the interface of the read channel integrated circuit 304. The data block portions 506, 508, 510, and 512 specify test signals that are applied to the interface of the read channel integrated circuit 304 for a period of time specified by the number of clock cycles of delay in the data block portion 504.

For example, in one embodiment of the invention, the data block portion 506 is a 1-bit data block [28] that specifies a value of a read gate interface signal rdgate to be applied to the rdgate port of the read channel integrated circuit 304. The value of rdgate may specify a logic “1” or a logic “0” to be applied to the rdgate port of the read channel integrated circuit 304 and held at that logic value for the specified number of delay in cknrz clock cycles as specified by the data block portion 504. Furthermore, the data block portion 508 is a 1-bit data block [29] that specifies a value of a write gate interface signal wrgate to be applied to the wrgate port of the read channel integrated circuit 304. The value of wrgate may specify a logic “1” or a logic “0” to be applied to the wrgate port of the read channel integrated circuit 304 and held at that logic value for the specified number of delay in cknrz clock cycles as specified by the data block portion 504. Moreover, the data block portion 510 is a 1-bit data block [30] that specifies a value of a servo gate interface signal to be applied to the servo port of the read channel integrated circuit 304. The value of servo may specify a logic “1” or a logic “0” to be applied to the servo port of the read channel integrated circuit 304 and held at that logic value for the specified number of delay in cknrz clock cycles as specified by the data block portion 504. In addition, the data block portion 512 is a 1-bit data block [31] that specifies a value of a rst_pinb interface signal to be applied to the rst_pinb port of the read channel integrated circuit 304. The value of rst_pinb may specify a logic “1” or a logic “0” to be applied to the rst_pinb port of the read channel integrated circuit 304 and held at that logic value for the specified number of delay in cknrz clock cycles as specified by the data block portion 504.

As further shown in FIG. 5, the data block 500 comprises a data block portion 514 that stores a 1-bit chan_rdy value [32] which is compared to a value of a chan_rdy interface signal output from the read channel integrated circuit 304. If the bit value of chan_rdy specified in the data block portion 514 matches the output value of the chan_rdy port of the read channel integrated circuit 304, then the test control signals specified by the values in blocks 506, 508, 510, and 512 are applied to the corresponding input ports of the read channel integrated circuit 304. In one embodiment of the invention, to compare the chan_rdy, a XNOR (exclusive NOR) gate is used, wherein one input comes from a memory register and a second input comes from an output of the read channel integrated circuit 304. An output of the XNOR gate is used as a trigger in the programmable state machine controller 312.

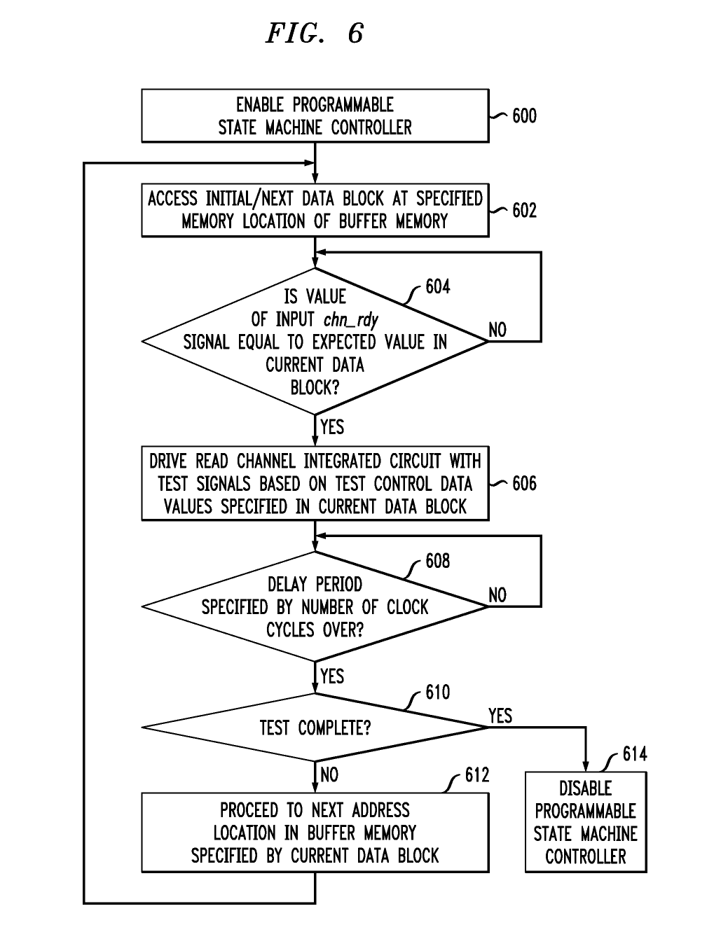

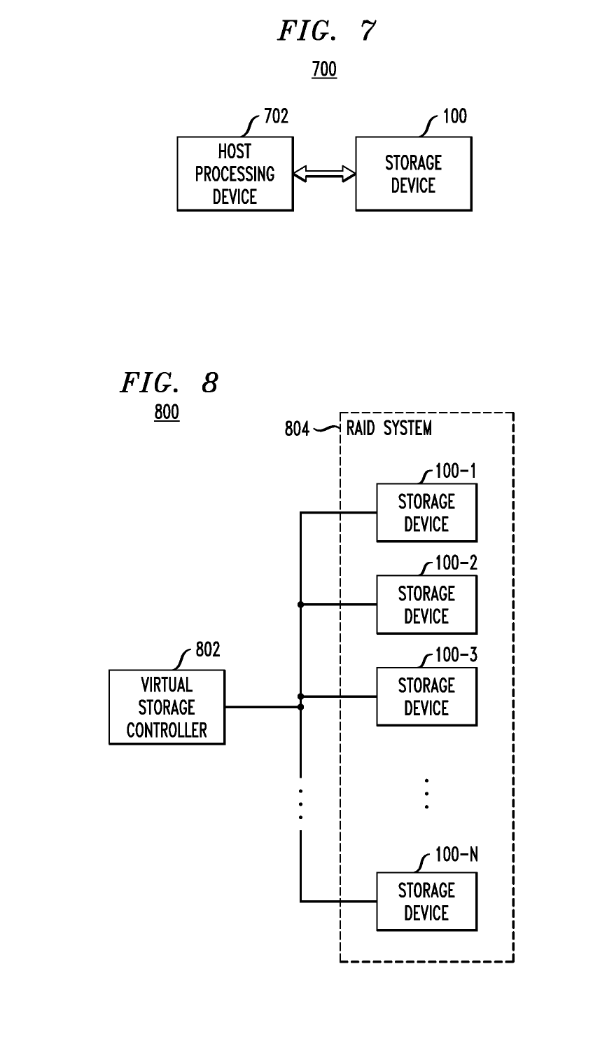

FIG. 6 is a flow diagram that illustrates a method for using a programmable state machine controller to generate test signals that drive a read channel integrated circuit to validate operation of components of the system-on-chip according to an embodiment of the invention. An initial step comprises enabling the programmable state machine controller to initiate a test mode (step 600). In one embodiment, this step is implemented by inputting a control signal via the JTAG interface 320 to initialize the programmable state machine controller 312 and inputting a control signal to the second multiplexer M2 to connect the programmable state machine controller 312 to the read channel integrated circuit 304. To begin a given test mode, the programmable state machine controller 312 will access an initial data block that is stored in memory (step 602). As noted above, a given test mode is executed by sequentially accessing and executing a series of linked data blocks stored in the buffer memory 314. The data blocks for a given test mode comprise a sequence of test control data that is sequentially processed by the programmable state machine controller 312 to generate test signals that are sequentially applied to drive the read channel integrated circuit 304.

After accessing the data block, the programmable state machine controller 312 will compare a current channel ready signal, chn_rdy, output from the read channel integrated circuit 304 with a value of the chn_rdy data block portion 514 specified in the currently accessed data block and wait to apply test signals to the read channel integrated circuit 304 until the channel ready signal, chn_rdy, output from the read channel integrated circuit 304 matches the value of the chn_rdy of the current data block (step 604). When the values match (affirmative result in step 604), the programmable state machine controller 312 will generate test signals based on the test control data specified in the currently accessed data block and drive the interface of the read channel integrated circuit 304 with the generated test signals (step 606). For example, the programmable state machine controller 312 will drive the read channel integrated circuit 304 with test signals using the rdgate, wrgate, servo and rst_pinb values specified in respective data block portions 506, 508, 510 and 512 of the currently accessed data block. These test signals for the current data block will be applied to the interface of the read channel integrated circuit 304 for a given period of time specified by the delay in number of block cycles value specified in the data block portion 504 of the currently access data block.

When the delay period expires (affirmative determination in step 608), a determination is made as to whether the test mode is complete (step 610). The current test mode is complete when the “next address location” value of the data block portion 502 of the currently accessed data block indicates that no further sequential data blocks exist for the given test mode. When the test mode is deemed complete (affirmative determination in step 610), the programmable state machine controller 312 is disabled (step 614). If the test mode is not complete (negative determination in step 610), the programmable state machine controller 312 will proceed to the next memory address location specified in the “next address location” data block portion 502 of the currently accessed data block (step 612). The programmable state machine controller 312 will access the next data block stored in the buffer memory at the specified next address location (return to step 602). Thereafter, the process flow will repeat steps 604, 606, 608, and 612 until the given test mode is complete.

As noted above, the JTAG interface 320 can be readily utilized to store test control data in the buffer memory 314 for various types of test modes for testing the impact of operation of the read channel integrated circuit 304 on various components of the system-on-chip 300. This provides flexible programmability of the programmable state machine controller 312, which allows a user to programming different behaviors of the programmable state machine controller 312. For example, in one embodiment of the invention as discussed above, the read channel integrated circuit 304 can be driven in a given test mode to recreate internally generated voltage supply transients during a functional mode of the read channel integrated circuit 304 and observe the impact of these transients on the performance of system components such as a memory controller and an external DDR memory. By incorporating the programmable state machine controller 312 as an integrated component of the system-on-chip, the interface signals of the read channel integrated circuit 304 can be run at actual functional frequency so that testing can be performed at close to real-time functional mode of operation. Moreover, a separate, external I/O test interface is not needed to input test signals for driving the read channel integrated circuit 304, which eliminates the need for routing test signals for the read channel integrated circuit 304 on existing slower communication busses of the system-on-chip 300, or having to add additional data/control busses to support and route the I/O test signals resulting in problematic routing issues and wiring congestion.

FIG. 8 illustrates a processing system 800 comprising a storage device 100 connected to a host processing device 802, which may be a computer, server, communication device, etc. Although shown as a separate element in this figure, the storage device 100 may be incorporated into the host processing device. Instructions such as read commands and write commands directed to the storage device 100 may originate from the processing device 802, which may comprise processor and memory elements similar to those previously described in conjunction with FIG. 3.

Multiple disk-based storage devices 100 may be incorporated into a virtual storage system 900 as illustrated in FIG. 9. The virtual storage system 900, also referred to as a storage virtualization system, illustratively comprises a virtual storage controller 902 coupled to a RAID system 904, where RAID denotes Redundant Array of Independent Disks. The RAID system more specifically comprises N distinct storage devices denoted 100-1, 100-2, . . . , 100-N, one or more of which are assumed to be configured to include embodiments of a system-on-chip with a programmable state machine controller for validating operation of the system-on-chip, such as shown in FIG. 3. These and other virtual storage systems comprising hard disk drives or other disk-based storage devices of the type disclosed herein are considered embodiments of the invention. The host processing device 802 in FIG. 8 may also be an element of a virtual storage system, and may incorporate the virtual storage controller 902.

In other embodiments of the invention, a programmable state machine controller can be programmed to operate other types of integrated circuits formed on a system-on-chip to validate operation of the system-on-chip. The system-on-chip can be a storage controller or another type of system-on-chip that is commonly used in other types of devices or systems. In one embodiment, a system-on-chip includes an integrated circuit, a programmable state machine controller, a buffer memory connected to the programmable state machine controller, and an interface for externally accessing the buffer memory and storing test control data in the buffer memory. In a test mode to validate operation of the system-on-chip, the programmable state machine controller is enabled to access test control data from the buffer memory, and process the test control data to generate test signals that are applied to operate the integrated circuit and validate operation of the system-on-chip based on the operation of the integrated circuit.

In this regard, although embodiments of the invention have been described herein with reference to the accompanying drawings, it is to be understood that embodiments of the invention are not limited to the described embodiments, and that various changes and modifications may be made by one skilled in the art resulting in other embodiments of the invention within the scope of the following claims.

What is claimed is:

1. A system-on-chip for controlling a storage system, the system-on-chip comprising:
a storage controller;
a read channel integrated circuit;
a programmable state machine controller;
a switching circuit to switchably connect one of the storage controller and the programmable state machine controller to the read channel integrated circuit;
a buffer memory connected to the programmable state machine controller;
an interface for externally accessing the buffer memory and storing test control data in the buffer memory;
wherein in a test mode to validate operation of the system-on-chip, the switching circuit is controlled to switchably connect the programmable state machine controller to the read channel integrated circuit, and the programmable state machine controller is enabled to access test control data from the buffer memory, and process the test control data to generate test signals that are applied to operate the read channel integrated circuit and validate operation of the system-on-chip based on the operation of the read channel integrated circuit.

2. The system-on-chip of claim 1, wherein the interface comprises a Joint Action Test Group interface.

3. The system-on-chip of claim 1, wherein the buffer memory is utilized to store data during a functional mode of operation of the system-on-chip.

4. The system-on-chip of claim 1, wherein the test mode to validate operation of the system-on-chip comprises the programmable state machine controller driving the read channel integrated circuit with the test signals to emulate voltage transients that are generated during a functional mode of operation of the read channel integrated circuit.

5. The system-on-chip of claim 4, wherein the voltage transients are generated to determine effects of operation of the read channel integrated circuit on a random access memory that is used by the storage controller when reading/writing data to a storage medium controlled by the system-on-chip.

6. The system-on-chip of claim 5, wherein the random access memory comprises an external double data rate synchronous dynamic random access memory.

7. The system-on-chip of claim 1, wherein the programmable state machine controller drives an interface of the read channel integrated circuit with the test signals to emulate read and write cycles that occur during a functional mode of operation of the system-on-chip.

8. The system-on-chip of claim 1, wherein the test control data stored in the buffer memory comprises a linked sequence of data blocks, wherein each data block comprises a data block format comprising a first data block portion that specifies an address location of a next data block in the linked sequence of data blocks, a second data block portion that specifies a number of clock cycles of delay, and one or more third data block portions that specify one or more interface signals that are applied to the read channel integrated circuit for a period of time specified by the number of clock cycles of delay in the second data portion.

9. A storage system comprising the system-on-chip of claim 1 for controlling read and write operations of a storage medium.

10. The storage system of claim 9, wherein the storage system comprise a hard disk storage system.

11. A storage device, comprising:
an assembly comprising a storage medium and a read/write assembly to read/write signals from/to the storage medium;
a preamplifier to amplify signals sent to and received from the read/write assembly; and
system-on-chip for controlling the assembly and preamplifier, the system-on-chip comprising:
a storage controller;
a read channel integrated circuit connected to the preamplifier and the storage controller;
a programmable state machine controller;
a switching circuit to switchably connect one of the storage controller and the programmable state machine controller to the read channel integrated circuit;
a buffer memory connected to the programmable state machine controller;
an interface for externally accessing the buffer memory and storing test control data in the buffer memory;
wherein in a test mode to validate operation of the system-on-chip, the switching circuit is controlled to switchably connect the programmable state machine controller to the read channel integrated circuit, and the programmable state machine controller is enabled to access the test control data from the buffer memory, and process the test control data to generate test signals that are applied to operate the read channel integrated circuit and validate operation of the system-on-chip based on the operation of the read channel integrated circuit.

12. A virtual storage system comprising the storage device of claim 11.

13. A method for validating operation of a system-on-chip that controls a storage device, the method comprising:
switchably connecting a programmable state machine controller to a read channel integrated circuit during a test mode of the system-on-chip;
enabling the programmable state machine controller to access test control data from a buffer memory connected to the programmable state machine controller; and
performing the test mode by the programmable state machine controller processing the test control data to generate test signals that are applied to operate the read channel integrated circuit and validate operation of the system-on-chip based on the operation of the read channel integrated circuit.

14. The method of claim 13, further comprising accessing the buffer memory to store one or more sets of test control data that is used to program the programmable state machine controller for different tests modes for validating operation of the system-on-chip.

15. The method of claim 14, wherein accessing the buffer memory comprises storing the one or more sets of test control data in the buffer memory using a Joint Action Test Group interface.

16. The method of claim 13, wherein performing the test mode comprises the programmable state machine controller processing the test control data to drive the read channel integrated circuit with test signals to emulate voltage transients that are generated during a functional mode of operation of the read channel integrated circuit.

17. The method of claim 16, wherein the voltage transients are generated to determine effects of operation of the read channel integrated circuit on a random access memory that is used by the storage controller when reading/writing data to a storage medium controlled by the system-on-chip.

18. The method of claim 17, wherein the random access memory comprises an external double data rate synchronous dynamic random access memory.

19. The method of claim 13, wherein performing the test mode comprises the programmable state machine controller driving an interface of the read channel integrated circuit with the test signals to emulate read and write cycles that occur during a functional mode of operation of the system-on-chip.

20. The method of claim 13, further comprising storing the test control data in the buffer memory as a linked sequence of data blocks, wherein each data block comprises a data block format comprising a first data block portion that specifies an address location of a next data block in the linked sequence of data blocks, a second data block portion that specifies a number of clock cycles of delay, and one or more third data block portions that specify one or more interface signals that are applied to the read channel integrated circuit for a period of time specified by the number of clock cycles of delay in the second data block portion.
